(19) United States
(12) Patent Application Publication
(10) Pub. No.: US 2015/0380615 A1
(43) Pub. Date: Dec. 31, 2015

(54) LIGHT EMITTING DIODES WITH IMPROVED EFFICIENCY

(71) Applicant: Paul A. Zimmerman, Phoenix, AZ (US)

(72) Inventor: Paul A. Zimmerman, Phoenix, AZ (US)

(21) Appl. No.: 14/317,721

(22) Filed: Jun. 27, 2014

(51) Int. Cl. H01L 33/58; H01L 33/62; H01L 33/48

(52) U.S. Cl. CPC H01L 33/58; H01L 33/483; H01L 33/62

(57) ABSTRACT

Light emitting diode assemblies having transparent covers that exhibit high indexes of refraction adjacent are provided. Covers comprise polymer composites comprising inorganic nanoparticles. Inorganic nanoparticles include nanoparticles of zirconium dioxide, hafnium dioxide, titanium dioxide, and combinations thereof.

### FIELD

The present disclosure relates generally to light emitting diodes (LEDs), high index of refraction materials, and polymer composites comprising nanoparticles.

### BACKGROUND

Light emitting diodes (LEDs) consume less power than incandescent and halogen lights for the same amount of light produced and have longer service lifetimes. Unlike fluorescent lights, LEDs contain no mercury. LEDs are typically built on a semiconductor wafer that is diced apart to make individual chips and the LED can be as small as 1 mm² or less. LEDs resemble basic p-n junction diodes however LEDs also emit light. LEDs are typically comprised of a semiconducting material doped with impurities to create a p-n junction. The wavelengths of light emitted by a LED depends on the material used to form the p-n junction and LEDs that emit near IR, visible, or near-UV light are all possible.

### BRIEF DESCRIPTION OF THE FIGURES

The material described and illustrated is provided to exemplify aspects and is not meant to limit scope. For simplicity and clarity of illustration, elements illustrated in the figures are not necessarily drawn to scale. Further, where appropriate, reference labels have been repeated among figures to indicate corresponding or analogous elements. In the figures:

FIG. 1 is a schematic diagram illustrating emission properties of a light emitting diode chip.

FIG. 2 illustrates a light emitting diode chip assembly package.

FIG. 3 shows a light emitting diode chip assembly comprising a cover adjacent to the light emitting diode chip.

FIG. 4 illustrates the refractive index for ZrO₂, HfO₂, and TiO₂ as a function of wavelength of light in the visible spectral and the near UV regions.

FIGS. 5A and 5B show the dependence of the refractive index for a polymer composite comprising HfO₂ nanoparticles and for the polymer without nanoparticles, respectively.

FIGS. 6A-6D show monomers useful to form polymer composites having high refractive indexes.

FIGS. 7A and 7B show absorption and refractive index characteristics for two different acrylate polymers.

### DETAILED DESCRIPTION

In the following description, numerous specific details are set forth in order to provide an understanding of certain embodiments. Embodiments may be practiced without one or more of these specific details and frequently specific details of one embodiment may be practiced with other disclosed embodiments, as will be apparent to one of skill in the art. In other instances, well-known features are not described in detail in order to not obscure the description.

Most materials used to form light emitting diode chips (LEDs) have high indexes of refraction. The large difference in refractive index for the LED versus the air or polymer at the air-LED or polymer-LED interface causes a significant amount of light to be reflected back into the LED. The reflection of light back into the LED causes reduction in the efficiency of light emission. Generally, a flat-surfaced uncoated LED chip (a LED, or a LED semiconductor chip) will emit light perpendicularly to the semiconductor surface and a few degrees to the side in a conical shape, which is sometimes referred to as the light cone or the escape cone. The maximum angle of incidence is referred to as the critical angle. When the critical angle is exceeded, the photons of light are reflected back into the LED. Although some of these internal reflections can escape through other crystalline faces, in the typical device, a significant number are not emitted and are lost as heat in the device.

LEDs are typically packaged or encapsulated using a polymer (plastic) material. A polymer casing, shell, or package can protect the LED and its associated wiring from damage. The polymeric casing can also provide a cover or lens that can act as a diffusing lens that allows light to be emitted at a higher angle of incidence from the LED than the angle of incidence at which a bare LED chip would be able to emit light.

LEDs have dramatically improved in efficiency over the past 10 years due in part to improved process capabilities and materials; however, significant tight is still lost due to internal reflection. Optimization of the refractive index (RI) between the LED and the polymer used to package the LED can improve LED light emission efficiency. Typical polymers used to package LEDs include, for example, silicone or silicon/epoxy co-polymer 1,2. For example, 1,2-epoxy-4-vinyl-cyclohexane with 1,3,5,7-tetramethycyclotetrasiloxane is a transparent silicon epoxy co-polymer. A higher RI material can potentially improve the light intensity by 30% or more.

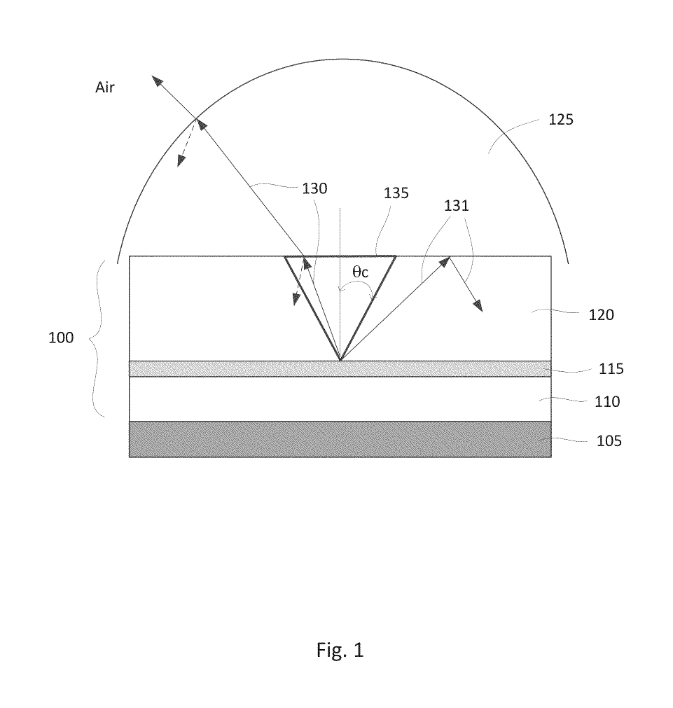

FIG. 1 illustrates some emission properties of a LED 100. In FIG. 1, a sub-mount 105 for LED chip 100 can include one or more heat sinks and electrical connections (not shown) for LED 100. In this example, which has been provided as an aid in understanding the disclosure, the LED 100 has been flip chip bonded to the sub-mount 105 and is comprised, in part, of GaN layers grown on a sapphire substrate. LED 100 has an active region 115, layers comprising GaN and a sapphire substrate region (shown as one region for clarity of illustration) 110, and layers comprising GaN 120. The active layer 115 is a region that is capable of emitting light when supplied with electrical energy and can be comprised of a multiple quantum well material (although other types of materials are possible). Other types of LEDs are also possible. A transparent polymer cover region 125 is adjacent to the region where light is emitted. The cover 125 is transparent to all or some of the light emitted by the LED 100. The cover 125 can have a dome shape and be larger than the LED 100 footprint. The larger size of the cover 125 as compared to the LED 100 reduces refraction (ray deviation) and total internal reflectance issues. Emitted light 130 originates in the active region 115 and leaves the LED 100 in an escape cone 135. Light 131 emitted from the active region 115 at an angle greater than θ_{c} is reflected back into the LED 100. Occasionally, emitted light 130 is reflected back into the LED 100 (as indicated by the dashed arrow). The angle associated with the escape cone 135, θ_{c}, can be determined from the equation: θ_{c}=sin⁻¹(nₜₒₚ/n_{sub}) where nₜₒₚ is the refractive index of the top material, which can be air or the polymer cover 125, and n_{sub} is the refractive index of the LED semiconductor material (for example, GaN). For a typical LED, the refractive index of the LED is about 2.45 and the refractive index of a silicone polymer is about 1.47, making θ_{c}=36.9 and 2θ_{c}=73.7.

The efficiency of the light production in a LED can be reduced in a second significant way which is also related to differences in refractive indexes between materials. The efficiency of light emission from the LIED 100 is described by the equation:

ηₑₓ=η_{esc}T_{SE}T_{EA}

where ηₑₓ is the extraction efficiency, η_{esc} is escape efficiency (the efficiency of light transfer from the semiconductor 100 to the polymer cover 125), T_{SE} is the transmission efficiency from the substrate to polymer or polymer composite layer, and T_{EA} is the transmission efficiency from the polymer or polymer composite layer to the air. The escape efficiency η_{esc}, can be described by the equation:

$${n}_{esc} = \frac{1 - \sqrt{1 - {( {n}_{e} / {n}_{s} )}^{2}}}{2}$$

T_{SE} can be described by the equation:

$${T}_{SE} = \frac{4 {n}_{s} {n}_{e}}{{( {n}_{s} + {n}_{e} )}^{2}}$$

and T_{EA} can be described by the equation:

$${T}_{EA} = \frac{4 {n}_{e}}{{( {n}_{e} + 1 )}^{2}}$$

where nₑ is the refractive index for a polymer cover 125 and nₛ is refractive index for the LED 100 material. Table 1 demonstrates the dependence of the extraction efficiency on the refractive index of the polymer cover 125 material. In Table 1, the substrate refractive index is taken to be 2.45.

TABLE 1

| | nₑ = 1.5 | nₑ = 2.0 | nₑ = 2.3 | nₑ = 2.45 |
|---|---|---|---|---|
| η_{esc} | 0.10 | 0.20 | 0.304 | 0.500 |
| T_{SE} | 0.93 | 0.987 | 0.998 | 1.00 |
| T_{EA} | 0.960 | 0.888 | 0.840 | 0.798 |
| ηₑₓ | 0.089 | 0.175 | 0.255 | 0.394 |

It can be seen from Table 1, that increasing the refractive index of the material directly on top of the LED substrate (the cover 125) is important to increasing the overall extraction efficiency for the LED. A cover 125 material having an index of refraction of 1.5 yields an overall extraction efficiency of 8.9% whereas a cover 125 material having an index of refraction of 2.45 yields an overall extraction efficiency of 39.4%.

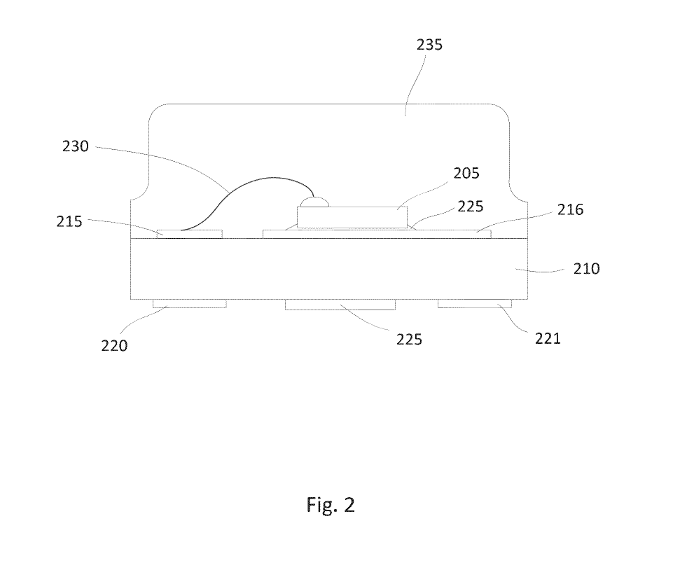

FIG. 2 shows an exemplary LED assembly package for a LED that functions as a light source. In FIG. 2, a LED die or chip 205 is mounted on a ceramic substrate 210. Contact pads 215 and 216 connect the LED 205 to power and optionally driving electronics (some or all driving circuits can be included in the LED 205). Contact pads 220 and 221 connect the LED 205 assembly to an external power source. A heat sink 225 provides heat management for the LED 205 during operation. A contact region 225 provides electrical connection between the contact pad 216 and the LED 205 (such as, for example, soldered pins or bumps, (not shown)) and may also include an under fill material. A wire bond 230 connects the LED 205 with the contact pad 215. A cover 235 is adjacent to the LED 205 and, in this assembly, covers the LED 205 and contact pads 215 and 216. Other shapes and designs are also possible for LEDs and packaging assemblies.

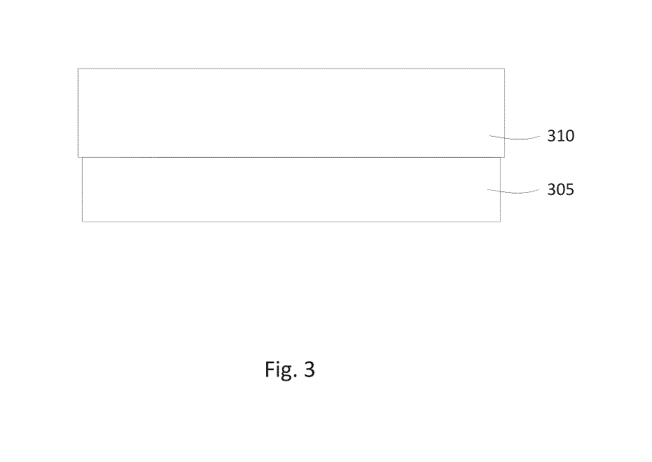

FIG. 3 illustrates a LED assembly in which a LED 305 is packaged with a transparent cover 310. The transparent cover 310 is transparent to some or all of the emission wavelengths of LED 305. Other shapes and sizes for transparent cover 310 are possible, such as for example, domed shapes.

Useful polymer materials for the covers 125, 235, and 310 that are adjacent to LED 100, 210, and 305 demonstrate photo and thermal stability and are transparent at desired LED emission wavelengths. in embodiments, polymers are stable up to at least 130° C., up to at least 140° C., or up to at least 150° C. Useful polymer materials include polymer composites comprising zirconium dioxide nanoparticles or hafnium dioxide nanoparticles. In embodiments, polymer composites comprise both nanoparticles of zirconium dioxide and nanoparticles of hafnium dioxide. In further embodiments, polymer composites comprise nanoparticles that comprise both zirconium and hafnium dioxide. In additional embodiments, polymer composites comprise titanium dioxide nanoparticles. In further additional embodiments, a polymer composite comprises titanium dioxide, zirconium dioxide, and/or hafnium dioxide nanoparticles. In additional further embodiments, individual nanoparticles of the polymer composite each comprise titanium, zirconium, and or hafnium dioxides. In embodiments, nanoparticles are between 1 and 5 nm in average diameter. Particles that are less than 5 nm in average diameter are smaller than the wavelengths of light emitted by typical LEDs, and allow light scattering by the nanoparticles to be minimized. Additionally, at these dimensions the nanoparticles can react with polymer monomers to create stable polymer matrices having properties of both the nanoparticles and the polymer base. In embodiments polymer composites have an inorganic content of between 35 weight % and 85 weight %. Inorganic materials are materials that essentially do not contain ca bon or hydrogen. Nanoparticles of zirconium dioxide, hafnium dioxide, and titanium dioxide are considered to be inorganic materials. One of skill in the art will recognize that it is unlikely that a material can be totally free from impurities or trace quantities of other substances, however, an inorganic material is considered to be without carbon or hydrogen even though it may contain trace, difficult to detect, or insignificant amounts of these elements.

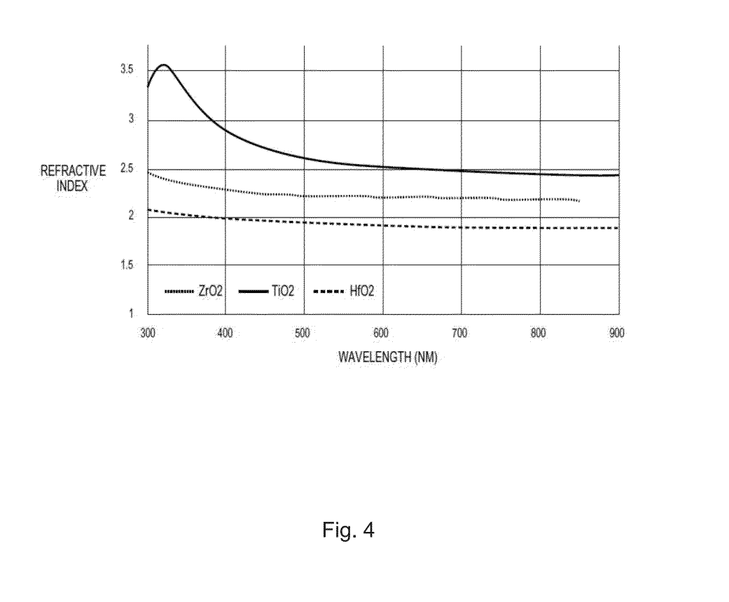

FIG. 4 illustrates the dependence of the refractive index of ZrO₂ and TiO₂ on wavelength of light. The refractive index for these inorganic materials is approximately 2.0-2.5 across the visible spectrum and these inorganic materials are also effectively transparent across the visible spectrum from 350 nm to 800 nm.

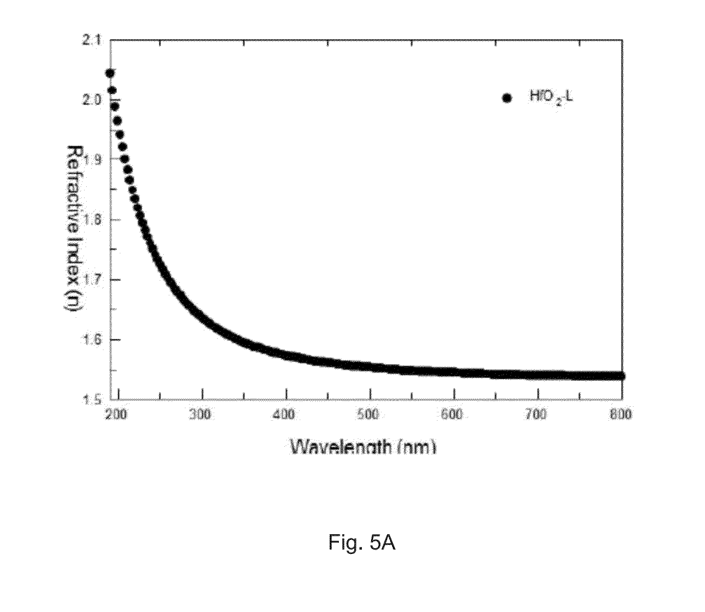

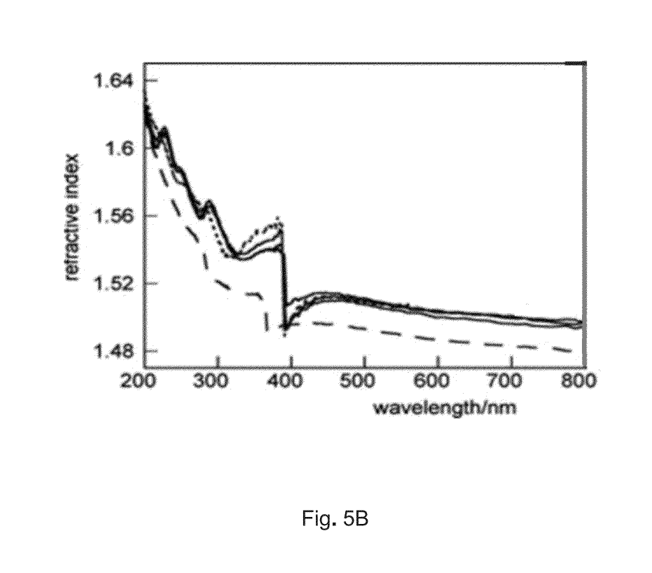

FIG. 5A shows the refractive index for polymer composite comprising HfO₂ nanoparticles. In this embodiment, the polymer was PMMA (poly methyl methacrylate) and the HfO₂ nanoparticles were present in a concentration of 30 weight % and had an average diameter of 1-2 nm. This polymer composite is transparent at wavelengths greater than 800 nm and is stable at least up to temperatures of 300° C. FIG. 5B shows a graph of the refractive index of a polymer, PMMA, versus the wavelength of light. The three different traces on the graph of FIG. 5B represent data from three different sources for the refractive index of PMMA. The polymer composite had a higher index of refraction than that of the polymer alone across the visible spectrum.

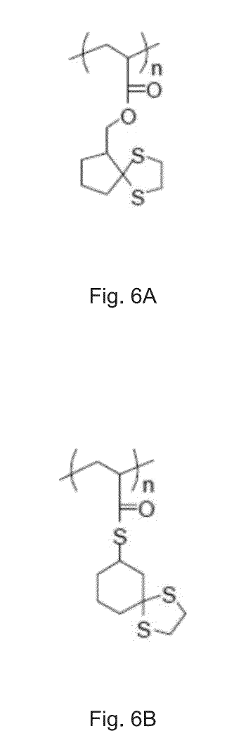

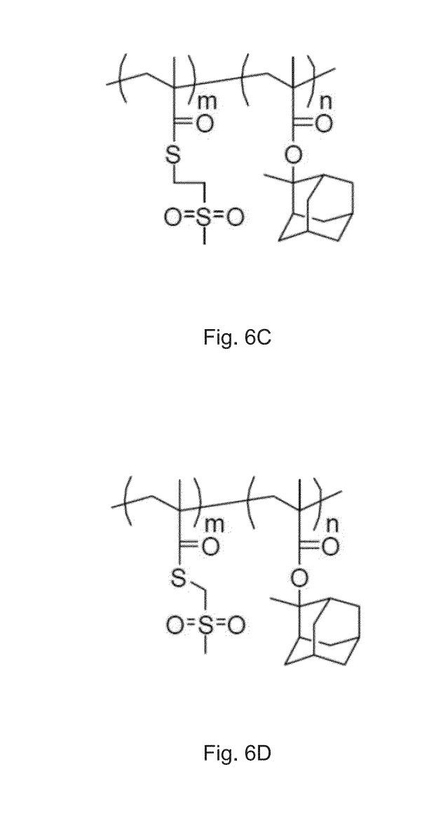

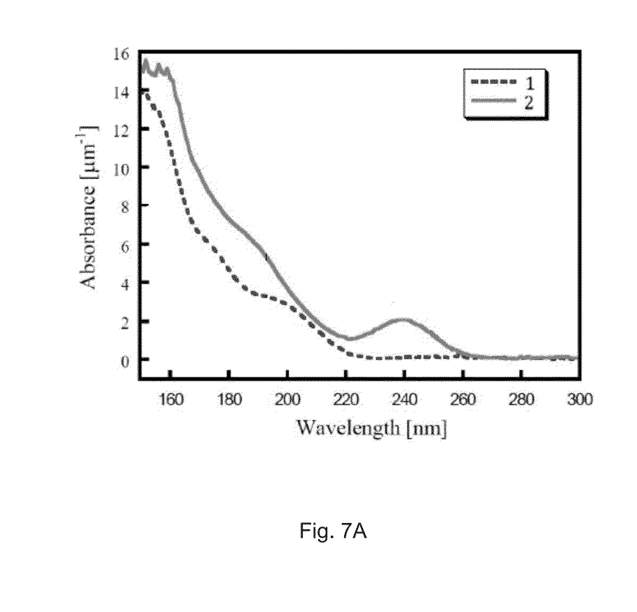

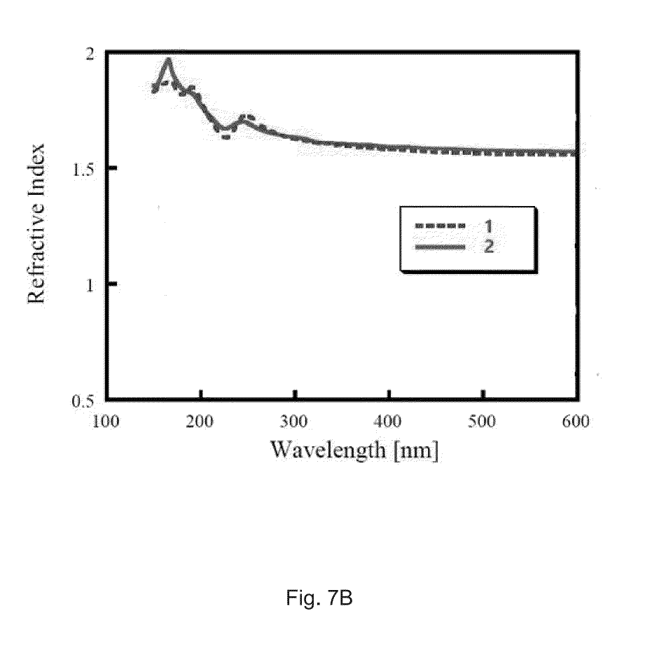

FIGS. 6A and 6B illustrate monomers that are also useful to form acrylate polymers for high RI polymer composites comprising inorganic nanoparticles. FIGS. 6C and 6D illustrate monomers that are useful to form methacrylate polymers for high RI polymer composites comprising inorganic nanoparticies. As discussed herein, inorganic nanoparticles include nanoparticles of ZrO₂, HfO₂, TiO₂, and combinations thereof. A polymer formed from the monomer of FIG. 6A has an index of refraction of 1.84 (measured at 193 nm) and a sulfur weight percent of 26.2 and a polymer formed from the monomer of FIG. 6B has an index of refraction of 1.94 (measured at 193 nm) and a sulfur weight % of 36.9. A polymer formed from the monomer of FIG. 6C has an index of refraction of 1.82 (measured at 193 nm) and a sulfur weight percent of 15.5 and a polymer formed from the monomer of FIG. 6D has an index of refraction of 1.82 (measured at 193 nm) and a sulfur weight % of 15.5. These polymers have thermal stability to greater than 250° C. and are capable of forming composites with inorganic nanoparticles. FIG. 7A illustrates absorption characteristics of a polymer formed from the monomers shown in FIGS 6A and 6B: graphs are labeled in the FIGS. “2” and “1,” respectively. FIG. 7B illustrates the refractive index characteristics a polymer formed from the monomers shown in FIGS. 6A and 6B: graphs are labeled in the FIGS. “2” and “1,” respectively.

In embodiments, useful polymers exhibit sulfur weight percentages of between 8 and 37 weight %. In embodiments, polymer composites exhibit refractive indexes of between 1.55 and 2.35, or between 1.60 and 2.35, or between 1.60 and 2.30, or between 1.65 and 2.30, or between 1.70 and 2.30, or between 1.70 and 2.25 at 500 nm. The refractive index of the polymer composite is in part dependent on the concentration of inorganic nanoparticles, such that higher concentrations of nanoparticles yield composites having higher indexes of refraction.

In general, a LED chip can comprise one light-emitting diode or an array of light-emitting diode regions. The LEDs of the array can be the same type of LED or the array can comprise different types of LEDs. LED chips can have a variety of sizes, wattages, color spectrums, and or number of LEDs. LED chips can also comprise additional electronics, such as, for example, LED drivers and dimmer circuits.

Substrates can include substrates that provide connections between and among electronic components, such as chips, and power supplies. Semiconductor and LED chips can be attached to one or both sides of the substrate. Substrates can be used to provide electrical connections between small-scale semiconductor chips and larger-scale power sources. Substrates can be, for example, wire boards or circuit boards.

Persons skilled in the relevant art appreciate that modifications and variations are possible throughout the disclosure as are substitutions for various components shown and described. Reference throughout this specification to “one embodiment” or “an embodiment” means that a particular feature, structure, material, or characteristic described in connection with the embodiment is included in at least one embodiment of the invention, but does not necessarily denote that they are present in every embodiment. Various additional layers and/or structures may be included and/or described features may be omitted in other embodiments.

1. A light emitting diode chip assembly comprising,
a light emitting diode chip wherein the light emitting diode chip has a surface,
a cover adjacent to the light emitting diode chip surface wherein the cover comprises a polymer composite comprising nanoparticles comprising zirconium dioxide, wherein the polymer is an acrylate polymer or a methacrylate polymer, and wherein the cover is transparent to at least some of the wavelengths of light that the light emitting diode chip is capable of emitting.

2. (canceled)

3. The assembly of claim 1 wherein the polymer comprises between 8 and 37 weight % sulfur.

4. The assembly of claim 1 wherein the nanoparticles have an average diameter of between 1 nm and 5 nm.

5. The assembly of claim 1 wherein the polymer composite comprises 35 to 85% by weight of nanoparticles.

6. The assembly of claim 1 wherein the polymer composite has a refractive index of between 1.70 and 2.30.

7. A light emitting diode chip assembly comprising,
a light emitting diode chip wherein the light emitting diode chip has a surface,
a cover adjacent to the light emitting diode chip surface wherein the cover comprises a polymer composite comprising nanoparticles comprising hafnium dioxide, wherein the polymer is an acrylate polymer or a methacrylate polymer, and wherein the cover is transparent to at least some of the wavelengths of light that the light emitting diode chip is capable of emitting.

8. (canceled)

9. The assembly of claim 7 wherein the polymer comprises between 8 and 37 weight % sulfur.

10. The assembly of claim 7 wherein the nanoparticles have an average diameter of between 1 nm and 5 nm.

11. The assembly of claim 7 wherein the polymer composite comprises 35 to 85% by weight of nanoparticles.

12. The assembly of claim 7 wherein the polymer composite has a refractive index of 1.70 and 2.30.

13. A light emitting diode chip assembly comprising,
a light emitting diode chip wherein the light emitting diode chip has a surface,
a cover adjacent to the light emitting diode chip surface wherein the cover comprises a polymer composite comprising nanoparticles comprising titanium dioxide, wherein the polymer is an acrylate polymer or a methacrylate polymer, and wherein the cover is transparent to at least some of the wavelengths of light that the light emitting diode chip is capable of emitting.

14. (canceled)

15. The assembly of claim 13 wherein the polymer comprises between 8 and 37 weight % sulfur.

16. The assembly of claim 13 wherein the nanoparticles have an average diameter of between 1 nm and 5 nm.

17. The assembly of claim 13 wherein the polymer composite comprises 35 to 85% by weight of nanoparticles.

18. The assembly of claim 13 wherein the polymer composite has a refractive index of between 1.70 and 2.30.

19. A light emitting diode chip assembly comprising,
a light emitting diode chip wherein the light emitting diode chip has a surface,
a cover adjacent to the light emitting diode chip surface wherein the cover comprises a polymer composite comprising an inorganic nanoparticles wherein the cover is transparent to at least some of the wavelengths of light that the light emitting diode chip is capable of emitting and the polymer composite has an index of refraction of 1.70 to 2.30, and
a substrate wherein the light emitting diode is attached to the substrate and forms electrical connections with the substrate.

20. The assembly of claim 19 wherein the inorganic nanoparticles comprise zirconium dioxide, hafnium dioxide, titanium dioxide, or a combination thereof.

21. The assembly of claim 19 wherein the nanoparticles comprise ZrO₂, HfO₂, or a combination thereof.

22. The assembly of claim 19 wherein the polymer is an acrylate or a methacrylate polymer.

23. The assembly of claim 19 wherein the nanoparticles have an average diameter of between 1 nm and 5 nm.

24. The assembly of claim 19 wherein the polymer composite comprises 35 to 85% by weight of nanoparticles.

25. The assembly of claim 19 or 22 wherein the polymer comprises between 8 and 37 weight % sulfur.

26. The assembly of claim 1 wherein the polymer composite has a refractive index of between 1.65 and 2.30.

27. The assembly of claim 7 wherein the polymer composite has a refractive index of between 1.65 and 2.30.

28. The assembly of claim 13 wherein the polymer composite has a refractive index of between 1.65 and 2.30.
